(19) United States
(12) Patent Application Publication
(10) Pub. No.: US 2010/0059367 A1
(43) Pub. Date: Mar. 11, 2010

(54) SPUTTER-COATING APPARATUS

(75) Inventor: HSIN-CHIN HUNG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/466,384

(22) Filed: May 14, 2009

(30) Foreign Application Priority Data
Sep. 11, 2008 (CN) 200810304473.5

(51) Int. Cl. C23C 14/34

(52) U.S. Cl. 204/298.07; 204/298.11

(57) ABSTRACT

A sputter-coating apparatus is configured for coating a substrate with a target material, and includes an upper housing defining an opening, a lower housing, an infrared heating unit, and a shielding member. The lower housing and the upper housing cooperatively defines an airtight chamber. The substrate and the target material are positioned in the lower housing. The infrared heating unit is fixed to the upper housing and configured for heating the substrate. The shielding member is fixed to the upper housing to seal the opening and is transparent to infrared rays generated by the infrared heating unit.

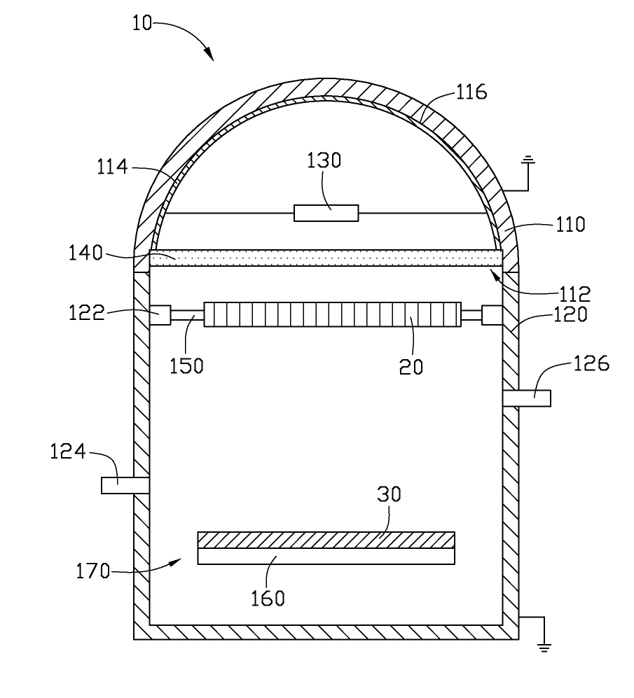

### BACKGROUND

1. Technical Field

The present disclosure relates to coating technology, and particularly to a sputter-coating apparatus.

2. Description of Related Art

Generally, in a sputter-coating process, an inert gas is excited in a chamber to release energetic ions. The energetic ions bombard a solid target material to vaporize the material. The vaporized material is then deposited on a substrate to be coated. During the process, an infrared heating unit is generally applied for heating the substrate to make vaporized material deposited on the substrate easier. However, the infrared heating unit is exposed in the chamber, which results that a normal working of the infrared heating unit is easily influenced by the energetic ions.

Therefore, what is needed is to provide a sputter-coating apparatus, which can overcome the above-mentioned problem.

### BRIEF DESCRIPTION OF THE DRAWINGS

The FIGURE is a schematic, sectional view of a sputter-coating apparatus, according to an exemplary embodiment.

### DETAILED DESCRIPTION

Referring to the FIGURE, a sputter-coating apparatus 10 for sputter-coating a substrate 20 with a target material 30, according to an exemplary embodiment, includes an upper housing 110, a lower housing 120, an infrared heating unit 130, a shielding member 140, an anode 150, and a cathode 160. The upper housing 110 and the lower housing 120 cooperatively define an airtight chamber 170. The substrate 20, the target material 30, the infrared heating unit 130, the shielding member 140, the anode 150 and the cathode 160 are positioned inside the airtight chamber 170.

The upper housing 110 is dome-shaped, and defines an opening 112 facing the lower housing 120. The upper housing 110 is made from a metallic material. The upper housing 110 includes a reflector 114 formed on an inner surface 116 of the upper housing 110. The reflector 114 may be coated with a reflective film, such as a titanium oxide film and a silicon oxide film.

The infrared heating unit 130 is fixed inside the upper housing 110 and is insulated from the upper housing 110. Part of infrared rays generated by the infrared heating unit 130 is reflected by the reflector 114 toward the lower housing 120. The shielding member 140 is fixed to the upper housing 110 to seal the opening 112 air tight. The shielding member 140 is made from a diamond-like carbon material or an aluminates glass material, such as calcium-aluminates glass, barium-aluminates glass, strontium-aluminates glass, magnesium-aluminates glass, and beryllium-aluminates glass, with a good optical performance and thermal performance.

One end of the lower housing 120 is open. The open end spatially corresponds to the opening 112 of the upper housing 110. The lower housing 120 is made from a metallic material and includes a rotating unit 122, a vacuum pump 124, and a gas inlet 126. The rotating unit 122 is fixed adjacent to the upper housing 110 and is configured for driving the substrate 20 to rotate. The vacuum pump 124 is mounted to one sidewall of the lower housing 120 and is configured for vacuumizing the airtight chamber 170. The gas inlet 126 is defined on another sidewall of the lower housing 120 and is configured for introducing an inert gas, such as an argon gas, or a krypton gas into the airtight chamber 170.

The substrate 20 and the anode 150 are fixed to the rotating unit 122 opposite to the infrared heating unit 130 and are rotatable jointly with the rotation of the rotating unit 122. The cathode 160 is fixed inside the airtight chamber 170 away from the upper housing 110. The target material 30 is positioned on the cathode 160 so that the target material 30 faces the substrate 20. Parts of infrared rays generated by the infrared heating unit 130 pass through the shielding member 140 to heat the substrate 20, and parts of the infrared rays are reflected by the reflector 114 toward the lower housing 120 through the shielding member 140.

When the inert gas is excited to release energetic ions, the shielding member 140 can prevent the infrared heating unit 130 from being influenced by the energetic ions. Therefore, a normal working of the sputter-coating apparatus 10 can be achieved.

It is to be understood, however, that even though numerous characteristics and advantages of the present embodiments have been set fourth in the foregoing description, together with details of the structures and functions of the embodiments, the disclosure is illustrative only, and changes may be made in details, especially in matters of shape, size, and arrangement of parts within the principles of the invention to the full extent indicated by the broad general meaning of the terms in which the appended claims are expressed.

What is claimed is:

1. A sputter-coating apparatus for coating a substrate with a target material, comprising:
an upper housing defining an opening;
a lower housing, the lower housing and the upper housing cooperatively defining a airtight chamber, the substrate and the target material positioned in the lower housing;
an infrared heating unit fixed to the upper housing and configured for heating the substrate; and
a shielding member fixed to the upper housing to seal the opening, the shielding member being transparent to infrared rays generated by the infrared heating unit.

2. The sputter-coating apparatus as claimed in claim 1, wherein the upper housing comprises a reflector having a concave reflecting surface for reflecting and directing the infrared rays to pass through the shielding member to the substrate.

3. The sputter-coating apparatus as claimed in claim 2, wherein the reflector is coated with a reflective film.

4. The sputter-coating apparatus as claimed in claim 3, wherein the reflective film comprises a titanium oxide film or a silicon oxide film.

5. The sputter-coating apparatus as claimed in claim 1, wherein the lower housing defines an open end spatially corresponding to the opening of the upper housing, the open end comprises a rotating unit, the rotating unit is fixed adjacent to the upper housing and is configured for driving the substrate to rotate.

6. The sputter-coating apparatus as claimed in claim 5, wherein the sputter-coating apparatus further comprises an anode and a cathode, the anode and the substrate are fixed to the rotating unit and is rotatable jointly with the rotation of the rotating unit, the cathode is fixed inside the airtight chamber away from the upper housing, the target material is positioned on the cathode and the target material faces the substrate.

7. The sputter-coating apparatus as claimed in claim 1, wherein the lower housing comprises a vacuum pump, the vacuum pump is mounted to one sidewall of the lower housing and is configured for vacuumizing the airtight chamber.

8. The sputter-coating apparatus as claimed in claim 7, wherein the lower housing comprises a gas inlet, the gas inlet is defined in another sidewall of the lower housing and is configured for introducing an inert gas into the airtight chamber.

9. The sputter-coating apparatus as claimed in claim 1, wherein the shielding member is made from a diamond-like-carbon material.

10. The sputter-coating apparatus as claimed in claim 1, wherein the shielding member is made from an aluminates glass material.

11. The sputter-coating apparatus as claimed in claim 10, wherein the aluminates glass is one of calcium-aluminates glass, barium-aluminates glass, strontium-aluminates glass, magnesium-aluminates glass, and beryllium-aluminates glass.
